(19) United States
(12) Patent Application Publication
(10) Pub. No.: US 2005/0189608 A1
(43) Pub. Date: Sep. 1, 2005

(54) [SHALLOW TRENCH ISOLATION AND METHOD OF FORMING THE SAME]

(76) Inventor: ERH-KUN LAI, HSINCHU (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/708,372

(22) Filed: Feb. 26, 2004

(51) Int. Cl. H01L 21/76

(52) U.S. Cl. 257/510

(57) ABSTRACT

A method of forming a shallow trench isolation (STI) is described. A substrate having a patterned hard mask thereon is provided. A trench is formed in the substrate by etching a portion of the substrate exposed by the hard mask layer. A first isolating layer is formed over the patterned hard mask layer and filling the trench. A liner layer is formed on the first insulating layer and on the remained hard mask layer. A second insulating layer is formed on the liner layer. A portion of the second insulating layer, a portion of the liner layer and a portion of the first insulating layer is removed until the mask layer is exposed. The patterned hard mask layer is removed. The liner layer covering the STI is thus formed.

### BACKGROUND OF INVENTION

1. Field of the Invention

The present invention relates, in general, to a shallow trench isolation and a method of forming the same. More particularly, the invention relates to a shallow trench isolation capable of preventing recess, dislocation, and silicon oxide loss problems, and a method for forming the same.

2. Description of the Related Art

Generally, a shallow trench isolation (STI) is formed by forming a trench in a semiconductor substrate and filling a silicon oxide layer into the trench. As the shallow trench isolation is scaleable to prevent the bird's beak encroachment in the prior technique of the field oxide isolation. It is a preferred technique applied to sub-micron fabrication process of semiconductors.

However, the conventional STI does not have any protective layer thereon, and therefore when the conventional STI is subjected to an external stress or a thermal effect during the subsequent process steps, dislocation problems between the STI and the substrate easily occur.

Additionally, in conventional methods, recesses are often found at the top corner of the STI after the step of removing the mask layer. The existence of recesses at the top corner of the STI deteriorates the isolating capability of the STI and thereby easily causes current leakage.

Normally, after an STI is formed, processes of forming active devices are initiated that may include several conventional photolithography and etching processes. Because the conventional STI does not have any protective layer thereon, and therefore the STI gets easily damaged in the subsequent etching process. Thus, the isolation capability of the STI is deteriorated.

### SUMMARY OF INVENTION

Accordingly, one objective of the present invention is to provide a shallow trench isolation and a method of forming the same in order to resolve problems due to recess at the top corner of the STI as in the case of the conventional art and thereby improve the isolating capability of the STI.

Another objective of this invention is to provide a shallow trench isolation and a method of forming the same to prevent dislocation problems even when an external stress or a thermal effect acts on the STI.

Another objective of this invention is to provide a shallow trench isolation and a method of forming the same to avoid silicon oxide loss from occuring during the subsequent etching step.

To achieve these and other advantages and in accordance with the purpose of the invention, as embodied and broadly described herein, this invention provides a shallow trench isolation comprising a substrate, an insulating layer and a liner layer. The substrate comprises a trench therein, and the insulating layer is disposed in the trench. The insulating layer has an upper surface higher than an upper surface of the substrate. The liner layer is disposed on the insulating layer. In a preferred embodiment, the liner layer further extends to the upper surface of the substrate. In another preferred embodiment, another insulating layer further covers the surface of the liner layer.

The invention also provides a method of forming a shallow trench isolation. A patterned mask layer is formed on a substrate. An etching process is performed using the patterned mask layer as a mask to for a trench in the substrate. A first insulating layer is formed over the patterned mask layer filling the trench. Such that a portion of the first insulating layer formed over the patterned mask layer are removed surrounding the trench remain exposed. Then, the exposed portion of the mask is removed using the first insulating layer as a mask. A liner layer is formed on the first insulating layer and on the remaining portion of the patterned mask layer. A second insulating layer is formed on the liner layer. A planarization process is performed to remove a portion of the second insulating layer, a portion of the liner layer, and a portion of the first insulating layer until the remaining portion of the patterned mask layer is exposed. Thereafter, the mask layer is removed for forming a shallow trench isolation.

The liner layer formed on the insulating layer serves as a protective layer and thereby prevent the dislocation problems from occurring even when an external stress or a thermal effect acts on the shallow trench isolation.

In addition, the liner layer formed on the insulating layer is also capable of protecting the STI from damage during the process of removing the patterned mask layer. Hence, formation of recesses at a top corner of STI as in the case of the conventional art can be avoided. Thus, the isolation capability of the STI can be promoted.

Moreover, the liner layer covering the insulating layer of the STI can serve to protect the insulating layer from damage in the subsequent etching process and therefore the silicon oxide loss during the etching process can be effectively prevented.

Both the foregoing general description and the following detailed description are exemplary and explanatory only and are not restrictive of the invention, as claimed.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The following drawings illustrate embodiments of the invention and, together with the description, serve to explain the principles of the invention.

FIG. 1 to FIG. 10 are schematic cross-sectional views showing the process steps of forming a shallow trench isolation according to one preferred embodiment of this invention.

FIG. 11 is a schematic cross-sectional view of a shallow trench isolation according to another preferred embodiment of this invention.

FIG. 12 is a schematic cross-sectional view of a shallow trench isolation according to another preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

FIG. 1 to FIG. 10 are schematic cross-sectional views showing the process steps of forming a shallow trench isolation according to one preferred embodiment of this invention. As shown in FIG. 1, a pad oxide layer 102, a mask layer 104 and a patterned photoresist layer 106 are sequentially formed on a substrate 100. In a preferred embodiment, a thermal oxidation process is performed to form the pad oxide layer 102 is formed. In a preferred embodiment, a chemical vapor deposition (CVD) process is performed to form the mask layer 104. In a preferred embodiment, the process of forming the patterned photoresist layer 106 includes, for example, performing a spin coating process to form a photoresist layer over the substrate 100, baking the photoresist layer to harden the photoresist layer and then patterning the photoresist layer by performing the conventional photolithography and etching process to form the patterned photoresist layer 106.

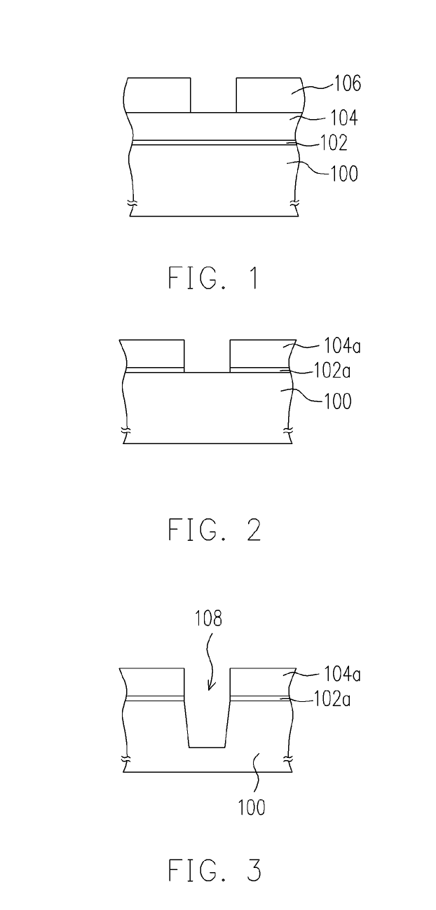

As shown in FIG. 2, an etching process is performed using the patterned photoresist layer 106 as etching mask to form a patterned mask layer 104a and a patterned pad oxide layer 102a. As shown in FIG. 3, the substrate 100 is etched using the patterned mask layer 104a as etching mask to form a trench 108 in the substrate 100.

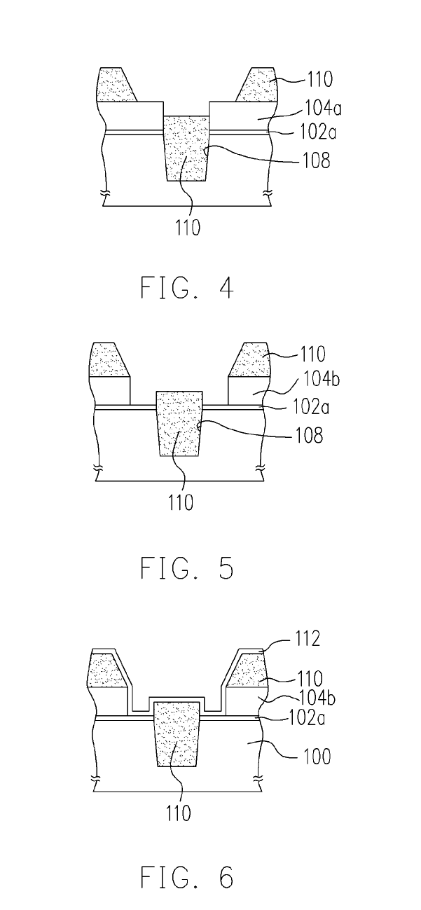

As shown in FIG. 4, a first insulating layer 110 is formed over the patterned mask layer 104a and filling the trench 108 such that a portion of the patterned mask layer 104a surrounding the trench 108 remains exposed. In a preferred embodiment, the first insulating layer 110 is a silicon oxide layer. In a preferred embodiment, the insulating layer 110 is formed by performing a high density plasma chemical vapor deposition (HDP-CVD) process. In a preferred embodiment, etching rate ratio, the deposition rate and the deposition time of the HDP-CVD process for forming the first insulating layer 110 are controlled such that the first insulation layer 110 is formed over the patterned mask layer 104a and fill the trench 108, wherein a portion of the patterned mask layer 110 surrounding the trench 108 remain exposed. For example, the HDP-CVD process is performed by charging the chemical recipes into the reaction chamber and then the HDP-CVD process is stopped before the first insulating layer 110 fills up the trench 108. As a result, the first insulating layer 110 can be formed in part over the patterned mask layer 104a and in part filling the trench 108 such that the first insulating layer 110 does not deposit over a portion of the patterned mask layer 104a surrounding the trench 108. Thus, a portion of the patterned mask layer 104a surrounding the trench 108 remains exposed. However, the present invention is not limited to performing HDP-CVD process for forming the first insulating layer 110. Other methods of forming the first insulating layer 110 that is capable of achieving the above profile can also be utilized. For example, a deposition process in combination with a suitable etching process can also be used to achieve the above profile to achieve the purpose of the invention.

As shown in FIG. 5, an etching process is performed to remove the exposed portion of the patterned mask layer 104a surrounding the trench 108 using the insulting layer 110 formed on the patterned mask layer 104a as an etching mask. As shown in FIG. 6, a liner layer 112 is formed on the first insulating layer 110 and on the remaining portion of the patterned mask layer 104b. In a preferred embodiment, the liner layer 112 is formed by performing a chemical vapor deposition (CVD) process. In a preferred embodiment, the liner layer 112 has a lower etching selectivity relative to the first insulating layer 110. In a preferred embodiment, the liner layer 112 is an insulating layer, such as a silicon nitride layer. Additionally, the liner layer 112 has a thickness between 50 angstrom to 200 angstrom, for example.

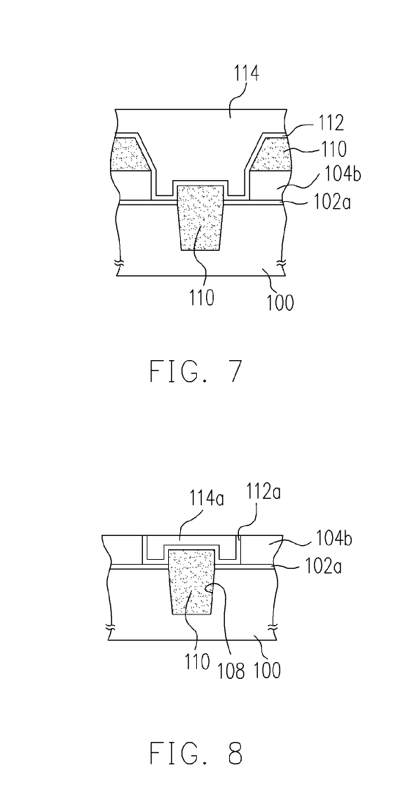

As shown in FIG. 7, a second insulating layer 114 is formed on the liner layer 112. In a preferred embodiment, the second insulating layer 114 is formed by performing a chemical vapor deposition (CVD) process. The second insulating layer 114 has a lower etching selectivity relative to the liner layer 112. In a preferred embodiment, the second insulating layer 114 is a silicon oxide layer.

As shown in FIG. 8, a planarization process is performed to remove a portion of the second insulating layer 114, a portion of the liner layer 112 and a portion of the first insulating layer 110 until the remaining patterned mask layer 104b is exposed, such that a remaining portion of the second insulating layer 114a, a remaining portion of the liner layer 112a and the first insulating layer 110 in the trench 108 are retained. In a preferred embodiment, the planarization process is, for example, a chemical mechanical polishing (CMP) process or an etch-back process.

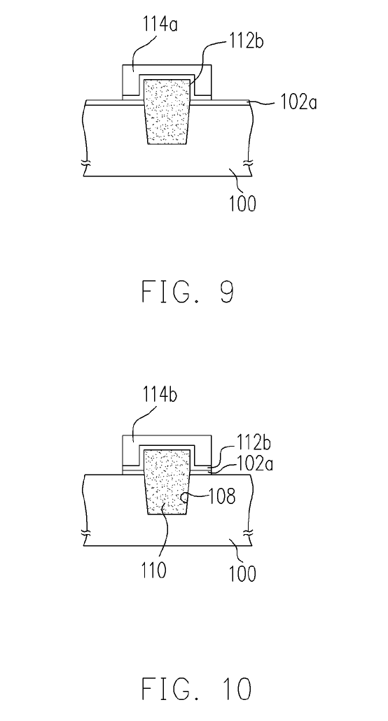

As shown in FIG. 9, the remaining patterned mask layer 104b and a portion of the remaining liner layer 112a not covered by the remaining second insulating layer 114a shown in FIG. 8 are removed. The remaining portion of the liner layer 112b covering the first insulating layer 110 is retained, and the remaining portion of the second insulating layer 114a and the pad oxide layer 102a are retained and exposed.

As shown in FIG. 10, the pad oxide layer 102a not covered by the liner layer 112 is removed, and the pad oxide layer 102b is formed to expose the surface of the substrate 100 for forming a shallow trench isolation. Especially, in a case, the second insulating layer 114a has a material similar to the pad oxide layer 102b that is silicon oxide. The second insulating layer 114a maybe loss to form a thinner second insulating layer 114b during the step of removing the pad oxide layer 102a not covered by the liner layer 112.

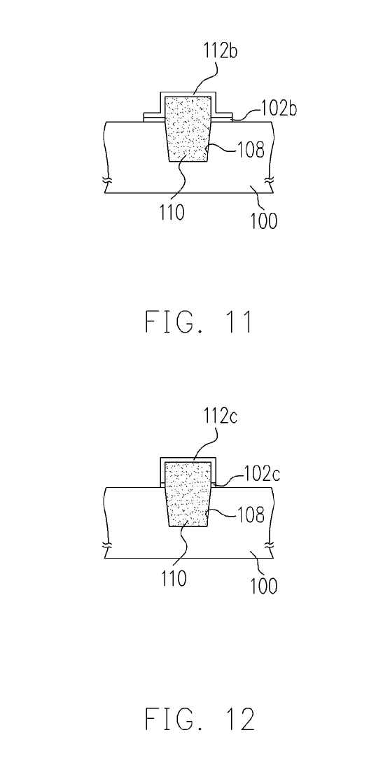

In another embodiment, the second insulating layer 114a may be removed completely during the step of removing the pad oxide layer 102b. Thus, the liner layer 112b under the second insulating layer 114a is exposed, and a shallow trench isolation is formed as shown in FIG. 11. The second insulating layer 114a may also be removed in other etching processes. The second insulating layer 114a is not limited to remove during the step of removing the pad oxide layer 102b.

FIG. 10 shows a shallow trench isolation fabricated according to said preferred embodiment of the present invention. The shallow trench isolation comprises a substrate 100, a liner layer 112b, a first insulating layer 110 and a second insulating layer 114b. The substrate 100 has a trench 108 therein, and the first insulating layer 110 is disposed in the trench 108. The first insulating layer 110 has an upper surface higher than the upper surface of the substrate 100. The liner layer 112b is disposed on the first insulating layer 110 exposed by the substrate 100, and extends to the upper surface of the substrate 100 form the first insulating layer 110. The second insulating layer 114b covers the surface of the liner layer 112b. In a preferred embodiment, a pad oxide layer 102c is disposed between the substrate 100 and the liner layer 112c.

In another preferred embodiment, the shallow trench isolation is shown in FIG. 11. The shallow trench isolation is similar to the shallow trench isolation of FIG. 10, and only has a difference at that the liner layer 112b is not covered by the second insulating layer 114b.

FIG. 12 shows a shallow trench isolation according to another preferred embodiment of the present invention. As shown in FIG. 12, the shallow trench isolation comprises a substrate 100, an insulating layer 110 and a liner layer 112c. The substrate 100 has a trench 108 therein, and the insulating layer 110 is disposed in the trench 108. The insulating layer 110 has an upper surface higher than the upper surface of the substrate 100. The liner layer 112c is disposed on the insulating layer 110 exposed by the substrate 100, but does not extend to the upper surface of the substrate 100. In a preferred embodiment, a pad oxide layer 102c is disposed between the substrate 100 and the liner layer 112c.

In the present invention, the liner layer covers the STI. The liner layer serves as a protective layer and is capable of preventing dislocation problems even when an external stress or a thermal effect acts on the shallow trench isolation.

Further, the liner layer covering the STI prevents the exposure of the STI to reaction conditions of the etching process used for removing the patterned mask layer and thereby protect the STI from damage. Thus, formation of recesses at top corners of the conventional STI can be effectively avoided and thereby the isolation capability of the STI can be effectively promoted.

In addition, the liner layer covering the STI prevents the exposure of the STI to the subsequent etching process conditions to effectively protect the insulating layer and thereby prevent any silicon oxide loss of the STI.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1-11. (canceled)

12. A shallow trench isolation, comprising:
a substrate, having a trench therein;
an insulating layer, disposed in the trench, wherein the insulating layer has an upper surface higher than an upper surface of the substrate; and
a liner layer, formed over the substrate covering the insulating layer, wherein the liner layer is adopted for protecting the shallow trench isolation from external stress or thermal effect.

13. The shallow trench isolation according to claim 12, wherein the liner layer further extends to an upper surface of the substrate.

14. The shallow trench isolation according to claim 12, wherein the liner layer has a low etching selectivity relative to the insulating layer.

15. The shallow trench isolation according to claim 12, wherein the liner layer has a thickness between 50 angstrom to 200 angstrom.

16. The shallow trench isolation according to claim 12, wherein the liner layer comprises an insulating layer.

17. The shallow trench isolation according to claim 16, wherein the liner layer is a silicon nitride layer.

18. The shallow trench isolation according to claim 12, further comprising a pad oxide layer formed between the liner layer and the substrate.

19. The shallow trench isolation according to claim 12, further comprising another insulating layer covering the liner layer.

20. A shallow trench isolation, comprising:
a substrate, having a trench therein;
an insulating layer, disposed in the trench, wherein the insulating layer has an upper surface higher than an upper surface of the substrate; and
a liner layer, formed over the substrate covering the insulating layer, wherein the liner layer comprises a CVD silicon nitride layer.

21. The shallow trench isolation according to claim 20, wherein the liner layer further extends to an upper surface of the substrate.

22. The shallow trench isolation according to claim 20, wherein the liner layer has a low etching selectivity relative to the insulating layer.

23. The shallow trench isolation according to claim 20, wherein the liner layer has a thickness between 50 angstrom to 200 angstrom.

24. The shallow trench isolation according to claim 20, wherein the liner layer comprises an insulating layer.

25. The shallow trench isolation according to claim 20, further comprising a pad oxide layer formed between the liner layer and the substrate.

26. The shallow trench isolation according to claim 20, further comprising another insulating layer covering the liner layer.
